(19) United States
(12) Patent Application Publication
(10) Pub. No.: US 2026/0148933 A1
(43) Pub. Date: May 28, 2026

(54) SUBSTRATE PROPERTY CONTROL USING DOSE-DEPENDENT RESPONSE

(71) Applicant: Applied Materials, Inc., Santa Clara, CA (US)

(72) Inventors: D. Jeffrey Lischer, Acton, MA (US); Morgan Evans, Manchester, MA (US); Jeffrey A. Morse, Center Tuftonboro, NH (US)

(73) Assignee: Applied Materials, Inc., Santa Clara, CA (US)

(21) Appl. No.: 19/057,513

(22) Filed: Feb. 19, 2025

Related U.S. Application Data
(60) Provisional application No. 63/724,031, filed on Nov. 22, 2024.

(51) Int. Cl. H01J 37/317; H01J 37/304

(52) U.S. Cl. CPC H01J 37/3171; H01J 37/304; H01J 2237/31703

(57) ABSTRACT

A method of managing a property of a substrate is provided. The method may include selecting an implant recipe according to a set of criteria for processing the substrate. The method may further include measuring a dose saturation curve for the implant recipe, determining an implant procedure based upon the implant recipe and the dose saturation curve; and implementing the implant procedure in the substrate using a processing system.

### RELATED APPLICATIONS

This application claims priority to U.S. provisional patent application Ser. No. 63/724,031, entitled SUBSTRATE PROPERTY CONTROL USING DOSE-DEPENDENT RESPONSE, filed Nov. 22, 2024, and incorporated by reference herein in its entirety.

### FIELD

The present embodiments relate to selective property control in substrates, and more particularly to selective dose implantation to selectively vary substrate properties.

### BACKGROUND

Devices such as integrated circuits, memory devices, and logic devices may be fabricated on a substrate such as a semiconductor wafer by a combination of deposition processes, etching, ion implantation, annealing, and other processes. Often, complete fabrication of devices and related circuitry may entail many hundreds of operations, including dozens of lithography operations. In particular, lithographic operations may require that a given pattern that is used to fabricate structures in a given region or level is to be aligned to preexisting structures.

A resulting problem with fabrication of substrates is the development of out-of-plane distortion (OPD) caused by stresses within the wafer, which distortion may be referred to as warpage. This OPD may be a result of stress that develops within the wafer as a result of processing. For example, a constant stress in a film stack on a wafer (substrate) will lead to a paraboloid shape of the wafer. This paraboloid shape can pose challenges to handling the wafer during downstream processing, and methods exist to correct the paraboloid shape effectively for downstream processing. However, patterning of these film stacks results in variations of the stress across the wafer, meaning along the main surface of the wafer, and leads to OPD shapes that are more complicated than a simple paraboloid. These more complicated shapes are more challenging to correct.

One approach to managing wafer (substrate) stress is to provide a stress compensation layer on a main surface of a substrate, which layer may be used counteract existing stress within the substrate and thus reduce OPD. In particular implementations, ion implantation has been used to implant ions into the stress compensation layer in order to attempt to alter the stress state locally and thus change the stress and OPD of the substrate. In some approaches, the dose of ions implanted into different regions of a substrate may be varied to account for local stress differences across the plane of the wafer. However, the present approaches may not take into account the most efficient manner to perform patterned implantation in order to achieve targeted change in substrate curvature.

A similar issue is present in the case where patterned implantation is to be performed to selectively control other substrate properties.

With respect to these and other considerations the present embodiments are provided.

### BRIEF SUMMARY

In one embodiment, a method of managing a property of a substrate is provided. The method may include selecting an implant recipe according to a set of criteria for processing the substrate. The method may further include measuring a dose saturation curve for the implant recipe, determining an implant procedure based upon the implant recipe and the dose saturation curve; and implementing the implant procedure in the substrate using a processing system.

In another embodiment, a method of managing a property of a substrate is provided. The method may include selecting a processing recipe involving a source of energy-imparting species for processing the substrate. The method may also include measuring a dose saturation curve for the processing recipe, determining an energy exposure process based upon the processing recipe and the dose saturation curve, and implementing the energy exposure process by directing processing species to the substrate from the source of energy-imparting species.

### BRIEF DESCRIPTION OF THE DRAWING

FIG. 1 depicts an exemplary system in accordance with embodiments of the present disclosure;

FIG. 2A shows a processing apparatus, depicted in schematic form, in accordance with embodiments of the present disclosure;

FIG. 2B. shows an extraction plate component and substrate in top plan view in accordance with embodiments of the present disclosure;

FIG. 3A is a presents an exemplary implant pattern;

FIG. 3B presents another exemplary implant pattern;

FIG. 4 is a graph that presents example dose saturation curves;

FIG. 5 is a graph that presents further dose saturation curves;

FIG. 6A is a composite illustration presenting an implant pattern and a graph showing implant response as a function of silicon ion dose for different dose ratios;

FIG. 6B is a composite illustration presenting an implant pattern and a graph showing implant response as a function of nitrogen ion dose for different dose ratios;

FIG. 7A is a graph presenting wafer throughput and OPD response for a first patterned implantation at two different total ion doses of silicon ions;

FIG. 7B is another graph presenting wafer throughput and OPD response for a second patterned implantation at two different total ion doses of silicon ions;

FIG. 7C is an additional graph presenting wafer throughput and OPD response for the first patterned implantation at two different total ion doses of nitrogen ions;

FIG. 7D is another graph presenting wafer throughput and OPD response for a second patterned implantation at two different total ion doses of nitrogen ions; and

FIG. 8 depicts an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved substrate property control. The present embodiments involve approaches to applying a variable dose of energy-imparting species across a substrate to more efficiently and effectively control substrate properties. In various embodiments, the energy-imparting species may be ions, energetic neutrals, photons, electrons, and so forth.

Various embodiments are especially suitable for controlling substrate properties in the case where non-uniform ion implantation is called for to address existing substrate configurations, such as OPD, non-uniform patterns of OPD, or non-uniform stress patterns across a substrate. The present embodiments are also suitable for the case where a non-uniform pattern of energy dose is to be imparted into a substrate, regardless of the existing substrate conditions. As detailed below, an approach to optimizing the imparted material response is based upon determining a dose-dependent response of a substrate to a given processing recipe for energy based processing. Unless otherwise noted, as used herein, the term “dose” may refer to a specific amount of energy-imparting species that are directed from a source of the energy-imparting species into a substrate in order to change the substrate properties, such as a dose of ions, does of photons, dose of electrons, dose of energetic neutrals, and so forth.

In particular embodiments, methods are disclosed to perform what may be termed selective implantation, where implant dose of an implant species is varied across a main surface of a substrate, using a beamline ion implanter, a compact ion beam tool, or other apparatus cable of varying implanted ion dose across a substrate. Some non-limiting examples of suitable apparatus are provided in the discussion to follow.

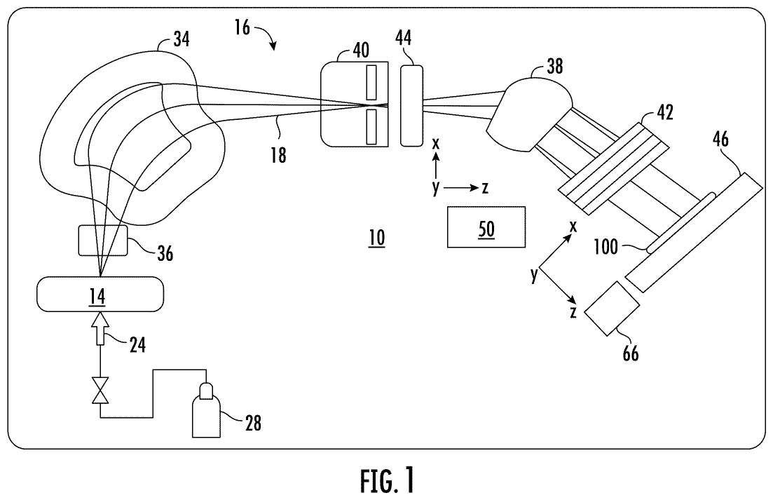

Referring now to FIG. 1, an exemplary system in accordance with the present disclosure is shown. The ion implantation system 10 may contain, among other components, an ion source 14 for producing an ion beam 18, an ion implanter, and a series of beam-line components 16. The ion source 14 may comprise a chamber for receiving a flow of gas 24 and generating ions therein. The ion source 14 may also comprise a power source and an extraction electrode assembly disposed near the chamber.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma source known to those skilled in the art.

The ion source 14 may generate the ion beam 18 for processing a substrate 100. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate).

In various embodiments, different species may be used as the ions to be used to deliver an energy-imparting dose of ions into the film. Non-limiting examples of suitable ions include silicon (Si), boron (B), carbon (C), oxygen (O), germanium (Ge), phosphorus (P), arsenic (As), inert gas ions, and so forth, such as other suitable ions, so as to alter substrate stress, substrate OPD, or other properties.

The beam-line components 16 may include, for example, a mass analyzer 34, a first acceleration or deceleration stage 36, a collimator 38, a mass resolving slit 40, and other suitable downstream beamline components such as an energy filter 42, to accelerate the ion beam 18, decelerate the ion beam 18, shape the ion beam 18, scan the ion beam 18, and so forth.

In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate 100 mounted on a platen 46 or clamp within a process chamber. As appreciated, the substrate may be moved using a control mechanism 66 in one or more dimensions (e.g., translate, including scanning, rotate, and tilt). As shown, there may be one or more feed sources 28 operable with the chamber of the ion source 14.

As an example, the ion implantation system 10 may include a scanner 44, to scan the ion beam 18. For example, the ion beam 18 may be provided as a spot beam that is scanned with the X-Y plane of the Cartesian coordinate system. For example, a scan generator (not separately shown) may deliver a scan signal, such as an oscillating voltage, to a pair of electrode plates that generate an oscillating electric field at a scan frequency in the kHz range, such as 1 kHz, 2 kHz, 5 kHz, according to some non-limiting embodiments.

In other embodiments, the scanner 44 may be omitted, and the ion beam 18 may be provided as an elongated ribbon beam having a long axis that extends along the X-axis, for example. In such embodiments, the substrate 100 may be scanned along the Y-axis, rotated within the X-Y plane, tilted with respect to the Z-axis, and so forth.

In particular embodiments, the ion beam 18 may be formed of an ion species having sufficient energy to implant into the substrate 100 (such as 100 eV, 1 keV, 10 keV, 100 keV, 500 keV, and so forth) as the substrate 100 is scanned with respect to ion beam 18, or as ion beam 18 is scanned with respect to substrate 100, resulting in an implanted dose of ions, where the dose of implanted ions may vary as a function of X-Y position.

As further shown in FIG. 1, the ion implantation system 10 may include a controller 50 to control operation of various components of the system 10, including components to scan the platen 46, to tilt the platen 46, to scan the ion beam 18, or to adjust the energy of the ion beam 18, for example. The controller 50 may further control operation of various components of the ion implantation system 10 to implement the methods as disclosed herein below.

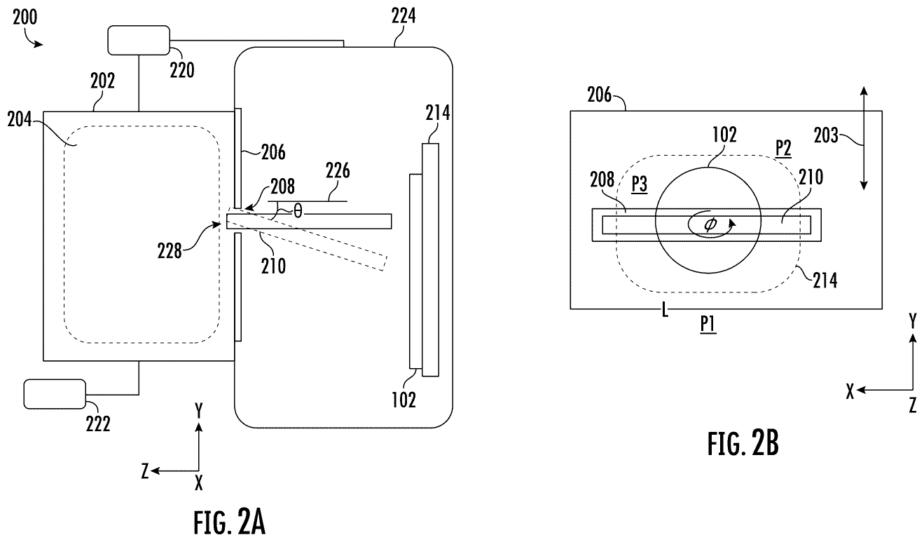

Turning now to FIG. 2A, there is shown a processing apparatus 200, depicted in schematic form. The processing apparatus 200 represents a processing apparatus for implanting ions into a substrate 102, and in particular, for implementing the methods as disclosed herein. The processing apparatus 200 may be a plasma based processing system having a plasma chamber 202 for generating a plasma 204 therein by any convenient method as known in the art. An extraction plate 206 may be provided as shown, having an extraction aperture 208, where a non-uniform ion implantation procedure or other non-uniform processing may be performed to selectively process a substrate 102 that is disposed in the process chamber 224. A substrate plane of the substrate 102 is represented by the X-Y plane of the Cartesian coordinate system shown, while a perpendicular to the plane of the substrate 102 lies along the Z-axis (Z-direction).

As further shown in FIG. 2A, an ion beam 210 may be extracted when a voltage difference is applied using bias supply 220 between the plasma chamber 202 and substrate 102, or substrate platen 214, as in known systems. The bias supply 220 may be coupled to the process chamber 224, for example, where the process chamber 224 and substrate 102 are held at the same potential.

According to various embodiments, the ion beam 210 may be extracted along the perpendicular 226 or may be extracted at a non-zero angle of incidence, shown as θ, with respect to the perpendicular 226. For example, the bias supply 220 may be configured to supply a voltage difference between plasma chamber 202 and process chamber 224, as a pulsed DC voltage, where the voltage, pulse frequency, and duty cycle of the pulsed voltage may be independently adjusted from one another.

In various embodiments, a gaseous species may be supplied by the source 222 to plasma chamber 202. The plasma 204 may generate a suitable ion species for implanting the substrate 102.

In various embodiments, the ion beam 210 may be provided as a ribbon ion beam having a long axis extending along the X-direction of the Cartesian coordinate system shown in FIG. 2B. By scanning a substrate platen 214 including substrate 102 with respect to the extraction aperture 208, and thus with respect to the ion beam 210 along the scan direction 230, the ion beam 210 may implant into the substrate 102 in a uniform on non-uniform manner, as a function of position within the X-Y plane. The ion beam 210 may be composed of any convenient ion mixture, including inert gas ion species, reactive gas ion species, elemental metallic ion species, elemental semiconductor ion species, molecular species, and so forth. In particular embodiments, the ion beam 210 may be formed of an ion having sufficient energy to implant into the substrate 102 as the substrate 102 is scanned with respect to ion beam 210, resulting in an implanted dose of ions, where the dose of implanted ions may vary as a function of X-Y position.

In this example of FIG. 2B, the ion beam 210 is provided as a ribbon ion beam extending to a beam width along the X-direction, where the beam width is adequate to expose an entire width of the substrate 102, even at the widest part along the X-direction. Exemplary beam widths may be in the range of 10 cm, 20 cm, 30 cm, or more while exemplary beam lengths along the Y-direction may be in the range of 2 mm, 3 mm, 5 mm, 10 mm, or 20 mm. The embodiments are not limited in this context.

Notably, the scan direction 230 may represent the scanning of substrate 102 in two opposing (180 degrees) directions along the Y-direction, or just a scan toward upwardly or a scan downwardly in the figure. As shown in FIG. 2B, the long axis of ion beam 210 extends along the X-direction, perpendicularly to the scan direction 230. Accordingly, an entirety of the substrate 102 may be exposed to the ion beam 210 when scanning of the substrate 102 takes place along a scan direction 230 to an adequate length from a left side to right side of substrate 102, as shown in FIG. 2B.

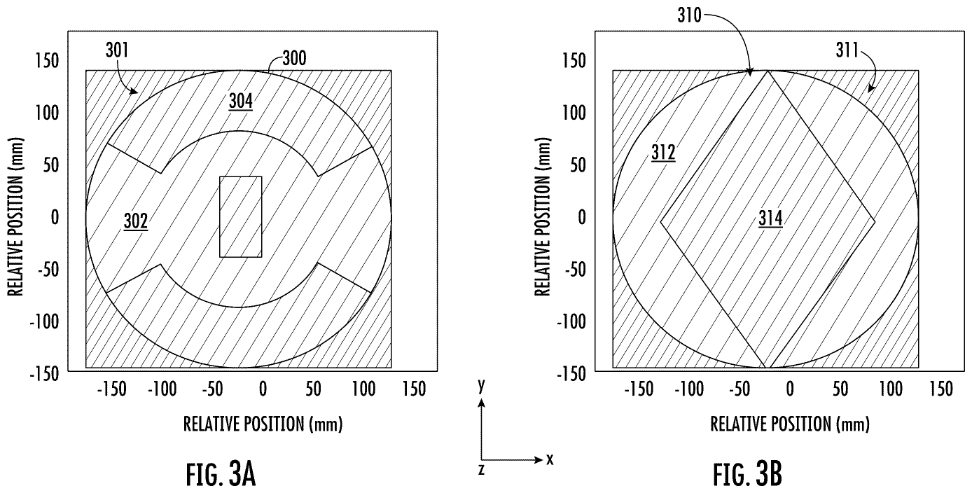

Turning to FIG. 3A, there is shown an exemplary implant pattern according to some non-limiting embodiments. The substrate 300 may be, for example, a semiconductor wafer, having a non-uniform distribution of properties across the X-Y plane, such as an OPD pattern. In this example, a particular OPD pattern within the substrate 300 may be addressed by applying an implant pattern 301 that applies an implant dose map (dose map) where the implant dose of ions that are implanted into the substrate 300 is varied according to position within the X-Y plane. In various embodiments, where OPD is to be corrected, the substrate 300 may include a stress compensation layer, such as silicon nitride, as in known stress compensation layer approaches. As suggested in FIG. 3A, this implant pattern may have a complex shape, and may entail varying the implant dose at different locations within the X-Y plane over a determined dose range. In this example, the determined dose range may correspond to the range of dose from a minimum dose to a maximum dose where the ratio of maximum dose in region 304 to minimum dose in region 302 is 5:1. Thus, to compensate for OPD, an ion beam (not shown, but see ion beam 18 or ion beam 210) may be scanned with respect to the X-Y plane and/or the substrate 300 may be scanned and or rotated with respect to the ion beam in a manner to impart a non-uniform ion dose into the substrate 300 over a dose range of 5:1.

Turning to FIG. 3B, there is shown another exemplary implant pattern according to some non-limiting embodiments. In this example, an implant pattern 311 that is applied to substrate 310 may be a regular pattern that is divided into quadrants, including low dose regions 312 and high dose region 314. The dose ratio between these regions may correspond to a dose range of 40:1. Again, to implement this implant pattern, a combination of substrate scanning and/or ion beam scanning may be performed to realize the called for ion doses within the substrate 300.

In the above examples, varying the implanted ion dose across the substrate has been shown to be effective ion compensating for existing substrate properties, such as OPD, including non-uniform OPD. As disclosed herein below, the present inventors have discovered that the ability to effectively change substrate properties by imparting a non-uniform dose into the substrate is dependent upon the absolute ion dose range that is employed.

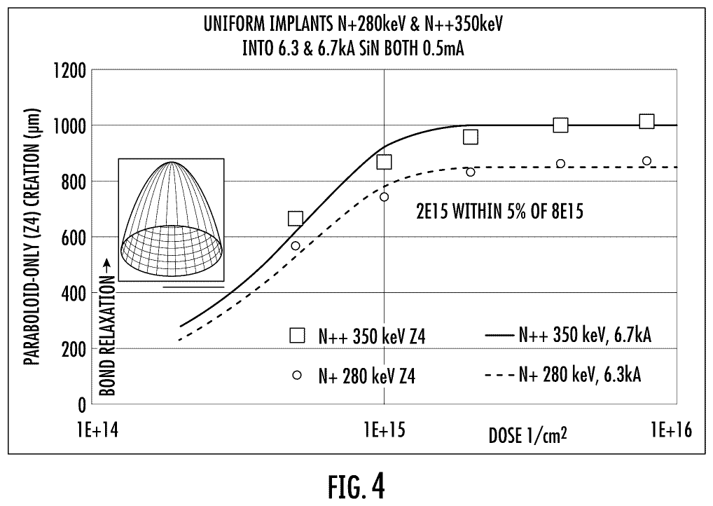

To explain the phenomenon of absolute dose range dependence, FIG. 4 is a graph of measured OPD response as a function of implanted ion dose, Nitrogen. In particular, FIG. 4 depicts the experimental results where nitrogen ions are implanted into a stress compensation layer that is disposed on a silicon wafer. The two different sets of data and corresponding curves correspond to N⁺⁺ ions implanted into a 670 nm thick SiN layer at 350 kcV and N+ ions implanted into a 630 nm thick SiN layer at 280 keV, respectively. The experimental results depicted in FIG. 4 are derived from a uniform implantation of Nitrogen ions into a uniform stress compensation layer disposed across a silicon wafer. Thus, the data of FIG. 4 are derived from a set of test substrates (silicon wafers) that are exposed to a uniform nitrogen ion implant, where each data point correspond to a uniform implant at a different combination of ion energy and ion dose. As such, the shape of the silicon wafer for each wafer may be modeled as a paraboloid. Note that the maximum value of the OPD is approximately 1 mm across a 300 mm diameter wafer. The results show that the OPD changes with increasing ion dose from a projected value of 200 micrometers in the low E14/cm² regime, to a saturation value of 1000 micrometers at approximately 2E15/cm². Above this ion dose, the OPD value does not substantially change. Without being bound by any theory, this behavior suggests that the maximum damage or rearrangement of the atoms within the SiN layer is imparted at the dose of 2E15/cm², which rearrangement results in a maximum relaxation of the stress state within the SiN layer and concomitant change in the curvature and OPD of the subjacent silicon substrate. In the regime of ion dose below 1 E15/cm² the data shows that OPD changes monotonically and somewhat linearly with change in ion dose.

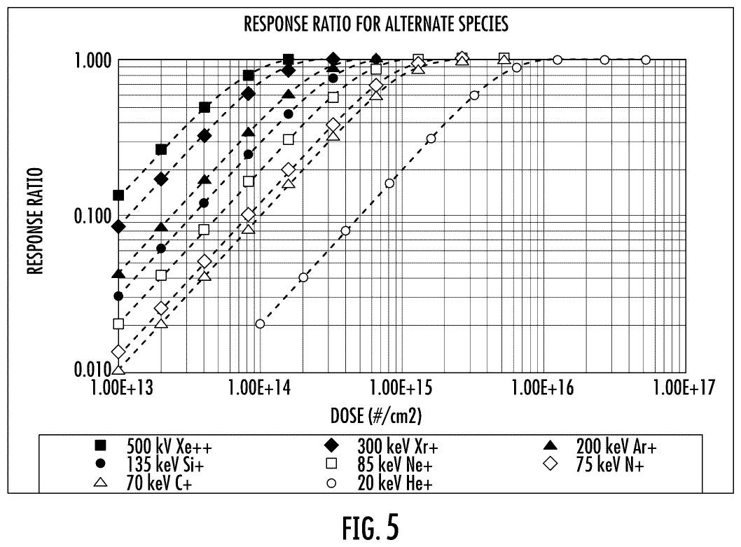

FIG. 5 is a graph similar to FIG. 4, and depicts a parameter that is termed the response ratio, again as a function of implanted ion dose. The response ratio is a normalized parameter that provides an indication of the relative changes in a layer being implanted. A relatively higher response ratio will indicate that a relatively larger change of an energy-treated film or layer will occur in response to the imparted energy from the ions.

In FIG. 5, the changes in response ratio are plotted for implantation of 8 different ion species, including He⁺, C⁺, N⁺, Ne⁺, Si⁺, Ar⁺, Kr⁺, and Xe⁺. The eight different curves all exhibit an increase in response ratio at low dose, followed by a saturation of response ratio at a given ‘critical’ dose that is species dependent. The saturation in the response ratio is interpreted to indicate that further increases in ion dose will not induce any further effective changes in materials properties within a layer being implanted, such as in the example of stress relaxation. Accordingly, each curve of FIG. 4 and FIG. 5 may be deemed to represent a dose saturation curve, where the response of a substrate to increased ion dose, such as the OPD in FIG. 4, saturates at a given ion dose for a given ion species, given ion energy, and given layer or material being implanted.

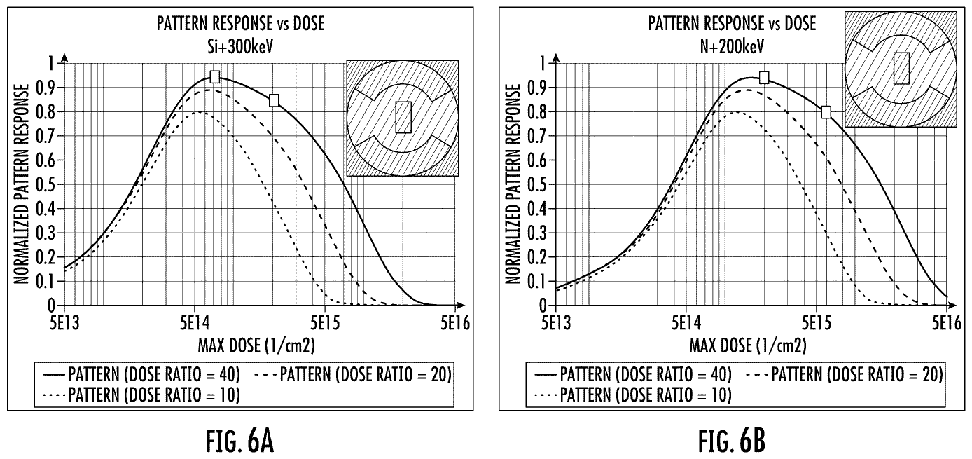

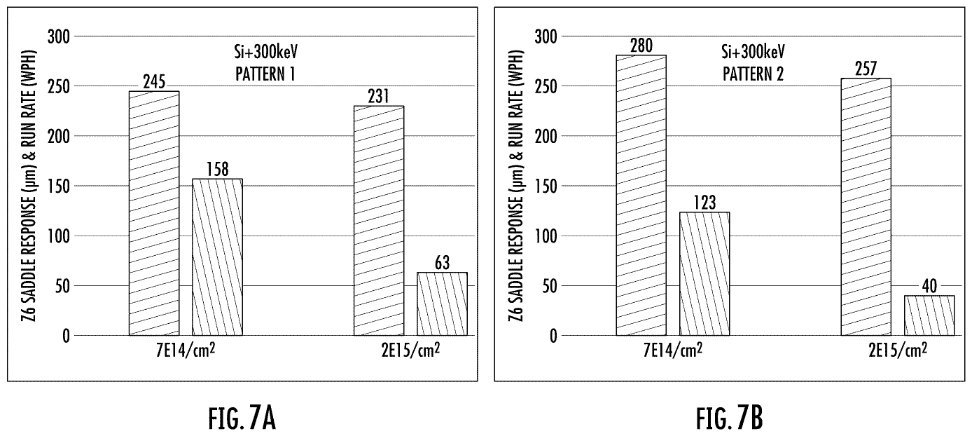

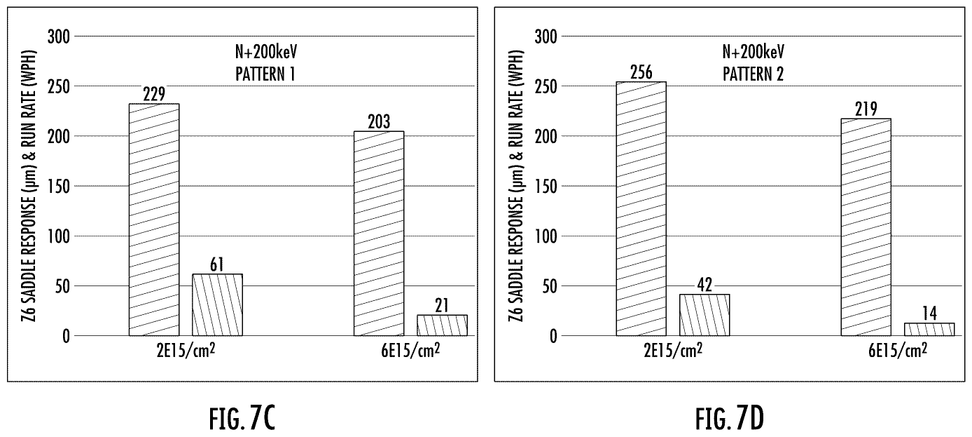

The above results may be harnessed in methods for controlling substrate properties, as described with respect to FIG. 6A to FIG. 7D. FIG. 6A and FIG. 6B present graphs that depict the calculated implant response as a function of ion dose for Si+ and N+, respectively, based upon the results of FIG. 5. The implant response is a normalized function that depicts the effectiveness of an implant procedure in changing a substrate property, in this case, depicting the effectiveness in reducing the OPD. The curves represent the case for a patterned implantation of silicon ions, such as in the design of patterned implantation shown above the graph. In this example, a relatively higher ion dose is implanted into the dark regions, while a relatively lower ion dose is implanted into the light regions. As shown, the implant response is highly dose dependent, in that the implant response rapidly increases at relatively lower ion dose as a function of increasing dose, and then gradually decreases to zero at relatively higher ion dose. The three curves represent the implant response function for different dose ratios-40:1. 20:1, and 10:1. At a 40:1 dose ratio, the implant response reaches a maximum of 94% at a dose of 7E14/cm² ion dose, while the maximum implant response at 20:1 and 10:1 are somewhat lower, at 90% and 80%, respectively, and may occur at slightly lower ion doses, of 6.5E14/cm² and 5.5E14/cm², respectively

At higher doses beyond the saturation dose or critical dose, the implant response decreases in the patterned implant examples. For example, in the curve for 40:1 dose ratio, the curve decreases to zero at approximately 3E16/cm² ion dose. This behavior may be understood as follows. Based upon the curve of FIG. 5, the response ratio for Si ions asymptotically approaches a maximum at approximately 6E14/cm² ion dose, above which dose the response ratio does not substantially increase. Thus, for example, the response ratio for Si ions implanted into a SiN layer (at a given ion energy) will not significantly change between the dose of 6E14/cm² and 3 E16/cm². Thus, for a dose ratio of 40:1, where the high implant regions are implanted with 3 E16/cm² the low implant regions will be implanted with 7.5E14/cm² ion dose. As shown in FIG. 5, both of these ion doses will induce the maximum response ratio. Thus, such a patterned implantation, where the dose ratio is 40:1 between different implant regions, will nonetheless generate the same response ratio (as shown in FIG. 5) across the substrate regardless of location, and therefore will not induce the desired location-dependent implant response. On the other hand, at 40:1 implant ratio and at 7E14/cm² maximum dose, the response ratio is at a maximum (100%), while the lower ion dose will correspond to 1.8 E13/cm² and a response ratio of 6%, leading to the maximum implant response of 94%. Thus, the implant response in this latter case (7E14/cm² ion dose) will be much higher than at higher total ion dose (3E16/cm²), as a difference between the response ratio at the two different ion doses.

The above results may be harnessed to more effectively and efficiently treat a substrate using patterned ion implantation, as demonstrated further in FIG. 7A, FIG. 7B, FIG. 7C, and FIG. 7D. FIG. 7A and FIG. 7B present the results of patterned implantation of 300 keV Sit ions into a silicon nitride stress compensation layer on a silicon wafer using a 40:1 dose ratio for two different ion doses. Similarly, FIG. 7C and FIG. 7D present the results of patterned implantation of 200 keV N⁺ ions into a silicon nitride stress compensation layer on a silicon wafer using a 40:1 dose ratio for two different ion doses. In FIG. 7A and FIG. 7C a first implant pattern is used, while in FIG. 7B and FIG. 7D a second implant pattern is used. The ion doses represent the greater ion dose, so that the lesser ion dose in the patterned implantation is 1/40 of the dose shown. The Y-axis of the four graphs represents either the relative OPD response of the substrate in micrometers, or alternatively, the substrate throughput of the substrates being processed in wafer starts per hour (WPH). Note in the case of 300 keV Sit ions that for both implant patterns, the change in OPD induced by the patterned implantation is greater (245 μm, 280 μm) at a maximum ion dose of 7 E14/cm² as opposed to an ion dose of 2 E15/cm² (231 μm, 257 μm). Moreover, the WPH is also greater (158, 123) at ion dose of 7 E14/cm² as opposed to an ion dose of 2 E15/cm² (63, 40). Similarly, for the case of 200 keV N⁺ ions for both implant patterns, the change in OPD induced by the patterned implantation is greater (229 μm, 256 μm) at a maximum ion dose of 2 E15/cm² as opposed to an ion dose of 6 E15/cm² (203 μm, 219 μm). Moreover, the WPH is also greater (61, 42) at ion dose of 2 E15/cm² as opposed to an ion dose of 6 E15/cm² (21, 14). The above results illustrate that, for a patterned implantation process, for multiple different ion species, the maximum ion dose selected for implantation into a substrate for a given dose ratio will substantially affect the efficiency of imparting a desired substrate response, as well as substrate throughput. To emphasize this point, the symbols provided in FIG. 6A for Si for the 40:1 dose ratio are indicative of the case for maximum dose of 7 E14/cm² and 2 E15/cm². Not only is the normalized pattern response higher for the lower maximum dose but the substrate throughput is also higher.

More generally, the present embodiments may be employed by using a dose response ratio curve to purposefully tune a procedure such as an implant procedure, by balancing out consideration of substrate response and substrate throughput, for example. In particular, a lower ion dose may be called for in a patterned implant procedure, where the substrate response at a relatively lower total ion dose is comparable to the substrate response io at a relatively higher total ion dose, such as within 10%, within 20%, or within any range of substrate response that is deemed suitable for a particular application. Thus, the elected implant procedure may employ the relatively lower ion dose to increase substrate throughput when a determination is made that the substrate response that is generated at the lower ion dose is acceptable, even if not as strong as the substrate response at the higher ion dose.

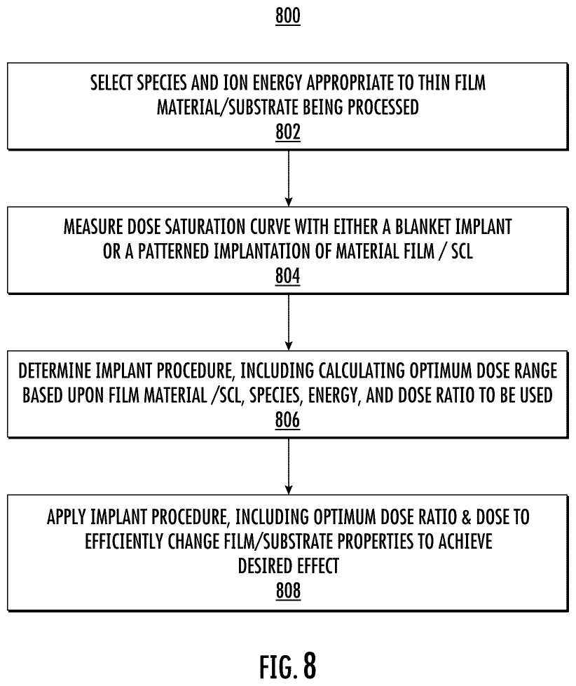

FIG. 8 presents a process flow 800, in accordance with some embodiments of the disclosure.

At block 802, an implant recipe, including, for example, an ion species and ion energy, is selected for implantation into a given layer system to be implanted, such as a combination of a thin film layer disposed on a substrate. In examples of patterned implantation, the implant recipe may include the pattern shape and the planned ion dose ratio for applying to different sections of the patterned shape. Among other considerations, the planned dose ratio may be determined by a calculated pattern shape, as well as the capabilities of a tool being used for the patterned implantation.

In embodiments for wafer stress management, the thin film material will correspond a pre-existing layer that is used, for example, as a mask layer or a deliberately deposited layer. In either case, the preexisting layer and the deliberately deposited layer will acts as a stress compensation layer (SCL) where implantation into the stress compensation layer is used to compensate for stress that has built up on the wafer, as a result of devices processing, such as forming CMOS devices, memory devices, and so forth. In various embodiments, the proper ion species and ion energy may be selected based upon known computer modelling approaches that determine the interaction of ions within a given material layer, based upon the implant energy, ion species, and layer material to be implanted.

At block 804, a dose saturation curve is measured for the layer system being processed. The dose saturation curve may be determined in the case of a uniform ion implantation in some examples, or in the case of a patterned ion implantation in other examples. In particular embodiments, the dose saturation curve may be determined for a stress compensation layer deposited on a semiconductor wafer, such as a silicon wafer.

At block 806, an implant procedure is determined, including calculating the optimum ion dose range for implantation into the given layer system (such as a thin film material, stress compensation layer, etc.), based upon the given ion species, ion energy, and dose ratio to be imparted into a substrate. The optimum ion dose range may refer to the range between a maximum ion dose to be imparted into regions of maximal implant and minimal ion dose to be imparted in other regions. In one example, in order to determine the optimum ion dose range, an implant response curve is determined based upon the dose saturation curve determined at block 804 and a given dose ratio to be implemented. In one variant, where certain considerations for patterned implantation dictate the use of a given dose ratio, the optimum ion dose may range be determined by determining a maximum implant response from a single implant response curve corresponding to the given dose ratio, as shown in FIG. 6. In another variant, where a range of dose ratios may be suitable for patterned implantation, multiple implant response curves may be calculated corresponding to multiple dose ratios, as shown in the multiple implant response curves of FIG. 6. The optimum ion dose range may then be selected based upon the multiple implant response curves. Other considerations for determining optimum ion dose range include the targeted throughput for wafer processing.

At block 808, the implant procedure, including the optimum ion dose and dose ratio, is applied for implantation into a substrate to efficiently change the film/substrate properties to achieve a desired effect, such as reduction in OPD of a substrate.

While the aforementioned embodiments may be employed to implant stress compensation layers that are provided on a substrate, in additional embodiments, the methods disclosed herein may be used to selectively implant any suitable substrate or substrate layer, where the effect of implantation is dose-sensitive, such as exhibiting a saturation in induced structural change or substrate property change as a function of increasing ion dose.

Moreover, in further embodiments, substrate property control may be carried out using other sources of energy-imparting species, such as light sources for photons or electron beam sources for electrons. For example, photons or electrons may be used to selectively expose a substrate to a variable energy dose based upon a preselected pattern, in order to control properties of the substrate, including stress or other properties. For these other energy-imparting species, such as photons, or electrons, the exact energy of such species may be readily determined according to the layer material and the layer thickness to be altered by the energy-imparting species. In these additional embodiments, a dose saturation curve and energy response curve may be determined for the given source of energy-imparting species, as well as the exact energy, where the dose saturation curve and energy response curve are analogous to those curves as disclosed with respect to FIGS. 5 and 6A-6B, respectively.

Advantages provided by the present embodiments are multifold. As a first advantage, a relatively higher substrate response may be induced by selecting the combination of proper total ion dose and dose ratio for patterned implantation. As an additional advantage, the present approach facilitates choosing implant conditions that lead to higher throughput of implanted wafers.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of managing a property of a substrate, comprising:
selecting an implant recipe according to a set of criteria for processing the substrate;
measuring a dose saturation curve for the implant recipe;
determining an implant procedure based upon the implant recipe and the dose saturation curve; and
implementing the implant procedure in the substrate using a processing system.

2. The method of claim 1, wherein the implant recipe includes an implant species and an implant energy.

3. The method of claim 1, wherein the set of criteria include at least one of:
a measured shape of the substrate;
a thickness of a layer, disposed on the substrate to be implanted; and
a composition of the layer.

4. The method of claim 2, wherein the measuring the dose saturation curve comprises:
implanting a set of test substrates at a plurality of ion doses, respectively, using the implant recipe, wherein over at least two different implant dose values, a value of a determined substrate property asymptotically approaches a maximum.

5. The method of claim 4, wherein the dose saturation curve is measured for a uniform implantation procedure or for a patterned implantation procedure.

6. The method of claim 4, wherein the determining the implant procedure comprises calculating an optimum ion dose range, based upon the dose saturation curve and the implant recipe.

7. The method of claim 6, wherein the implant procedure is a non-uniform ion implant procedure, and wherein the optimum ion dose range is further based upon a dose ratio for the non-uniform ion implant procedure.

8. The method of claim 3, wherein the measured shape of the substrate is a map of out-of-plane distortion of the substrate, and wherein the layer is a stress compensation layer to be implanted.

9. A method of managing a property of a substrate, comprising:
selecting a processing recipe involving a source of an energy-imparting species for processing the substrate;
measuring a dose saturation curve for the processing recipe;
determining an energy exposure process based upon the processing recipe and the dose saturation curve; and
implementing the energy exposure process by directing processing species to the substrate from the source of energy-imparting species.

10. The method of claim 9, wherein the processing recipe is an implant recipe that includes an implant species and an implant energy for an implant procedure.

11. The method of claim 9, wherein the selecting the processing recipe is based upon a set of criteria that include at least one of:
a measured shape of the substrate;
a thickness of a layer, disposed on the substrate to be implanted; and
a composition of the layer.

12. The method of claim 10, wherein the measuring the dose saturation curve comprises:
implanting a set of test substrates at a plurality of ion doses, respectively, using the processing recipe, wherein over at least two different implant dose values, a value of a determined substrate property asymptotically approaches a maximum.

13. The method of claim 12, wherein the dose saturation curve is measured for a uniform implantation procedure or for a patterned implantation procedure.

14. The method of claim 12, wherein the determining the energy exposure process comprises calculating an optimum ion dose range, based upon the dose saturation curve and the implant recipe.

15. The method of claim 14, wherein the implant procedure is a non-uniform ion implant procedure, and wherein the optimum ion dose range is further based upon a dose ratio for the non-uniform ion implant procedure.

16. The method of claim 11, wherein the measured shape of the substrate is a map of out-of-plane distortion of the substrate, and wherein the layer is a stress compensation layer to be implanted.

17. The method of claim 9, wherein the energy imparting species comprises energetic neutrals, photons, or electrons.

18. The method of claim 12, wherein the energy exposure process is an ion implantation process that is based upon the processing recipe, wherein the ion implantation process comprises a selected ion dose that is based upon the dose saturation curve, wherein the selected ion dose is chosen to increase substrate throughput.

19. The method of claim 18, wherein the ion implantation process is a patterned implant, and wherein the selected ion dose is based upon a normalized pattern response for the patterned implant, the normalized pattern response depicting an effectiveness of the ion implantation process in changing a substrate property.
